(19) United States
(12) Patent Application Publication
(10) Pub. No.: US 2024/0304473 A1
(43) Pub. Date: Sep. 12, 2024

(54) METHODS AND APPARATUS TO PLACE BALLS FOR SECOND LEVEL INTERCONNECTS OF INTEGRATED CIRCUIT PACKAGES

(71) Applicant: Intel Corporation, Santa Clara, CA (US)

(72) Inventors: Zewei Wang, Chandler, AZ (US); George Frank Robinson, JR., Chandler, AZ (US); Tingting Gao, Chandler, AZ (US); Viet Chau, Vancouver, WA (US)

(21) Appl. No.: 18/179,092

(22) Filed: Mar. 6, 2023

(51) Int. Cl. H01L 21/67; H01L 21/48

(52) U.S. Cl. CPC H01L 21/67121; H01L 21/4853; H01L 23/49816; H01L 23/49833; H01L 23/49838

(57) ABSTRACT

Methods, apparatus, systems, and articles of manufacture to place balls for second level interconnects of integrated circuit packages are disclosed. An example apparatus includes a ball head including a first surface having an array of holes. The array of holes hold a corresponding array of solder balls to be placed on a package substrate of an integrated circuit package. The apparatus also includes a protrusion extending away from the surface of the ball head. The protrusion is positioned relative to the holes to contact a second surface of the package substrate when the solder balls are to be placed on the package substrate.

### FIELD OF THE DISCLOSURE

This disclosure relates generally to integrated circuit packages and, more particularly, to methods and apparatus to place balls for second level interconnects of integrated circuit packages.

### BACKGROUND

In many integrated circuit packages, one or more semiconductor dies are mechanically and electrically coupled to an underlying package substrate. Many such package substrates include an array of contacts (e.g., a ball grid array (BGA), a land grid array (LGA), or a pin grid array (PGA)) to enable the package to be mechanically and electrically coupled to a printed circuit board.

### BRIEF DESCRIPTION OF THE DRAWINGS

FIG. 1 illustrates an example integrated circuit (IC) package constructed in accordance with teachings disclosed herein.

FIG. 2 illustrates an example ball placement system constructed in accordance with teachings disclosed herein to place solder balls onto the package substrate of the example IC package of FIG. 1.

FIG. 3 illustrates the example ball head of example ball placement system of FIG. 2 after being pressed down on the package assembly.

FIG. 4 is similar to FIG. 3 but after the example ball head has released or dropped the balls onto the package substrate.

FIG. 5 is an enlarged view of a portion of the example ball head demarcating dimensions associated with the balls and the protrusions shown in FIGS. 2-4.

FIGS. 6-8 are similar to FIG. 5 but showing different example cross-sectional shapes for the example protrusions.

FIG. 9 is a bottom view of the example ball head of FIG. 2.

FIGS. 10-12 are similar to FIG. 9 but showing different example layouts and/or locations for the example protrusions.

FIG. 13 is a flowchart representative of an example method of implementing the example ball placement system of FIGS. 2-4 to manufacture the example IC package of FIG. 1.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description. As used herein “substantially real time” refers to occurrence in a near instantaneous manner recognizing there may be real world delays for computing time, transmission, etc. Thus, unless otherwise specified, “substantially real time” refers to real time +/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

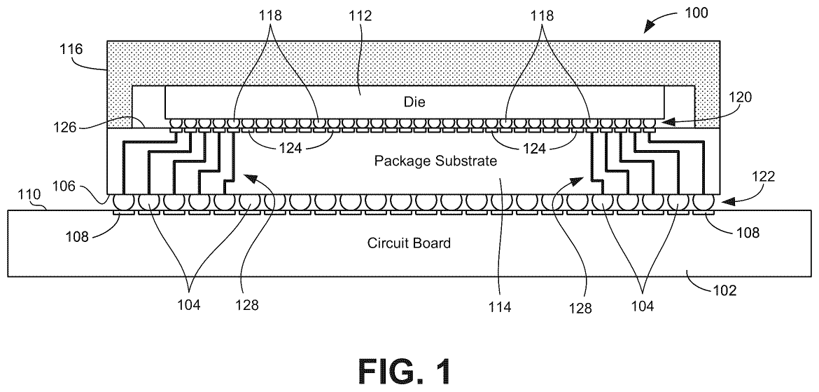

FIG. 1 illustrates an example integrated circuit (IC) package 100 constructed in accordance with teachings disclosed herein. In the illustrated example, the IC package 100 is electrically coupled to a circuit board 102 via an array of bumps or balls 104 (e.g., a ball grid array (BGA)) that protrude from a mounting surface (e.g., an external surface) 106 of the package 100. In this example, the bumps 104 are electrically coupled to corresponding contacts or landing pads 108 on a facing mounting surface (e.g., a top surface) 110 of the circuit board 102. In this example, the landing pads 108 are flush with the top surface 110 of the circuit board 102. In other examples, the landing pads 108 are inset relative to the top surface 110. In other examples, the landing pads 108 protrude beyond the top surface 110. In this example, the package 100 includes a semiconductor (e.g., silicon) die 112 that is mounted to a package substrate 114 and enclosed by a package lid or mold compound 116. While the example IC package 100 of FIG. 1 includes a single die 112, in other examples, the package 100 may have more than one die (e.g., two or more positioned side-by-side on the package substrate 114 and/or two or more stacked on top of one another). The die 112 can provide any suitable type of functionality (e.g., data processing, memory storage, etc.).

As shown in the illustrated example, the die 112 is electrically and mechanically coupled to the package substrate 114 via a corresponding array of bumps or balls 118. The electrical connections between the die 112 and the package substrate 114 (e.g., the bumps 118) are sometimes referred to as first level interconnects 120. By contrast, the electrical connections between the IC package 100 and the circuit board 102 (e.g., the bumps 104) are sometimes referred to as second level interconnects 122. In some examples, when more than one die is included in the package 100, the dies may be stacked on top of one or more other dies and/or an interposer. In such examples, the dies are coupled to the underlying die and/or interposer through a first set of first level interconnects and the underlying die and/or interposer may be connected to the package substrate 114 via a separate set of first level interconnects associated with the underlying die and/or interposer. Thus, as used herein, first level interconnects refer to bumps or balls or other types of interconnects) between a die and a package substrate or a die and an underlying die and/or interposer.

As shown in FIG. 1, the bumps 118 of the first level interconnects 120 are physically connected and electrically coupled to contact pads 124 on an inner surface 126 of the substrate 114. The contact pads 124 on the inner surface 126 of the package substrate 114 are electrically coupled to the bumps 104 on the bottom (external) surface 106 of the substrate 114 (e.g., a surface opposite the inner surface 126) via internal interconnects 128 within the substrate 114. As a result, there is a complete signal path between the bumps 118 of the die 112 and the landing pads 108 on the circuit board 102 that pass through the contact pads 124, the interconnects 128, and the bumps 104 provided therebetween. The interconnects 128 are shown as simple lines in the illustrated example of FIG. 1 for purposes of illustration. However, the internal interconnects 128 may be implemented by traces or electrical routing in different metal layers within the substrate 114 that are separated by layers of dielectric material. The traces in the different metal layers are electrically coupled by metal vias extending through the layers of dielectric material.

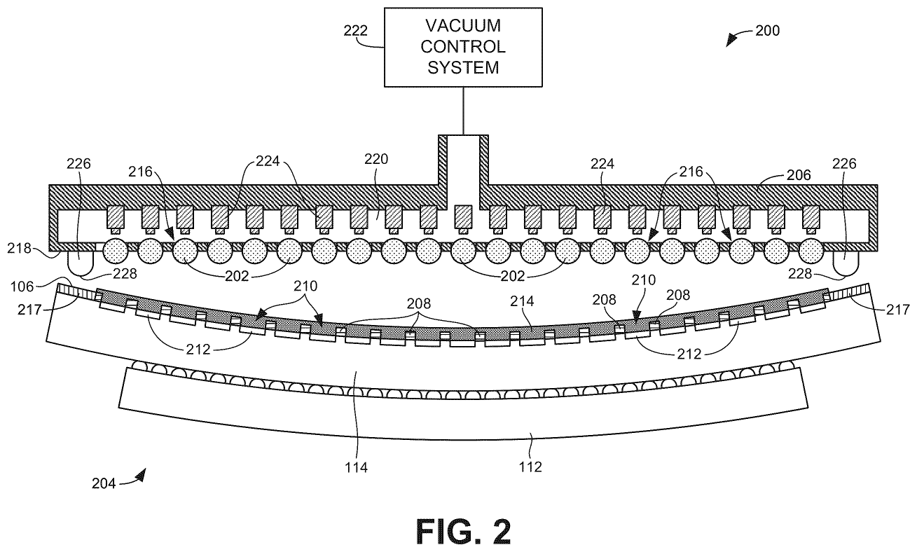

The manufacturing of the package 100 of FIG. 1 includes separately fabricating the die 112 and the package substrate 114 and then mounting or attaching the die 112 to the package substrate 114. In some examples, the array of bumps 104 (corresponding to the second level interconnects 122) are added to the external surface 106 of the package substrate 114 after the die 112 is attached to the substrate 114. The die attach process typically involves relatively high temperatures being applied to provide reliable electrical and mechanical connections for the first level interconnects 120. Due to differences in the coefficients of thermal expansion (CTE) of the materials in the die 112 relative to the CTE of the materials in the package substrate 114, the die 112 and the substrate 114 are likely to expand and/or contract in size at different rates during the temperature changes associated with the die attach process. The differences in expansion and/or contraction often result in some warpage or bending of the die 112 and/or the substrate 114. Such warpage can present challenges to the accurate placement of the bumps 104 on the external surface 106 of substrate 114 to provide the second level interconnects 122 as detailed further below in connection with FIG. 2.

FIG. 2 illustrates an example ball placement system 200 constructed in accordance with teachings disclosed herein to place solder balls 202 onto the package substrate 114 of the example IC package 100 of FIG. 1. More particularly, the solder balls 202 shown in FIG. 2 are to become the bumps 104 corresponding to the second level interconnects 122 shown and described in connection with FIG. 1. For purposes of explanation, the term “balls” is used to refer to the solder prior to being attached to the package substrate and the term “bumps” is used to refer to the solder after attachment and subsequent processing (e.g., including heat treatment). However, it should be understood that the bumps 104 on the final IC package 100, shown in FIG. 1, may also be referred to as balls.

In FIG. 2, the die 112 and the package substrate 114 are shown as being warped due to the temperatures associated with attaching the die 112 to the package substrate 114. The warpage can be relatively large (e.g., greater than 300 microns of variation in height across the surface 106), especially for relatively large packages. In the illustrated example, the warpage is exaggerated for purposes of explanation. The die 112 attached to the package substrate 114 represented in FIG. 2 (prior to the adding of the balls 202 and the package lid 116) is referred to herein as a package assembly 204 to distinguish it from the complete IC package 100 of FIG. 1. Notably, the package assembly 204 shown in FIG. 2 is flipped over relative to the orientation of the final IC package 100 shown in FIG. 1. That is, in FIG. 2, the external surface 106 of the package substrate 114 is facing up instead of down (as in FIG. 1) to enable the placement of the balls 202 thereon. Specifically, the orientation shown in FIG. 2 is used because the placement of the balls 202 relies on gravity to drop the balls 202 held by a ball head 206 of the ball placement system 200 as discussed more fully below.

As detailed in the illustrated example of FIG. 2, a significant portion of the external surface 106 is defined by a solder resist 208 that includes an array of openings 210 (e.g., solder resist openings) at locations where the solder resist 208 has been lithographically removed to expose underlying contacts 212. The underlying contacts 212 are electrically coupled to the internal interconnections 128 shown and described above in connection with FIG. 1. In this example, different ones of the solder resist openings 210 are arranged along the surface 106 of the package substrate 114 at locations corresponding to the final position of the balls 202 associated with the bumps 104 defined for the second level interconnects 122. Thus, individual ones of the solder resist openings 210 are to receive corresponding ones of the balls 202 held by the ball head 206 as shown in FIG. 2.

As shown in FIG. 2, a solder flux material 214 (sometimes referred to simply as flux) covers the solder resist 208 and fills the solder resist openings 210. Thus, as shown in the illustrated example, the flux material 214 covers a significant portion (e.g., a substantial majority) of the external surface 106 of the package substrate 114. In this example, the flux material 214 extends continuously across the solder resist 208 and solder resist openings 210. However, in other examples, individual and discrete portions of the flux material 214 may be deposited in individual ones of the solder resist openings 210. In the illustrated example, while the flux material 214 covers most of the external surface 106 of the package substrate 114, there are at least some regions 217 of the external surface 106 (at the outer edges or perimeter of the package substrate 114) that are not defined by the solder resist 208 and are not covered by the flux material 214.

In some examples, the flux material 214 is a relatively viscous fluid that helps to catch and retain the balls 202 in the respective solder resist openings 210 once the balls 202 are dropped from the ball head 206. Additionally, the flux material 214 helps improve the quality and reliability of the mechanical and electrical connections between the balls 202 and the corresponding contacts 212 at the bottom of the solder resist openings 210 following subsequent processing (e.g., heating the assembly to melt the balls 202 to create the final bumps 104 based on metallurgical bonds between the balls 202 and the contacts 212).

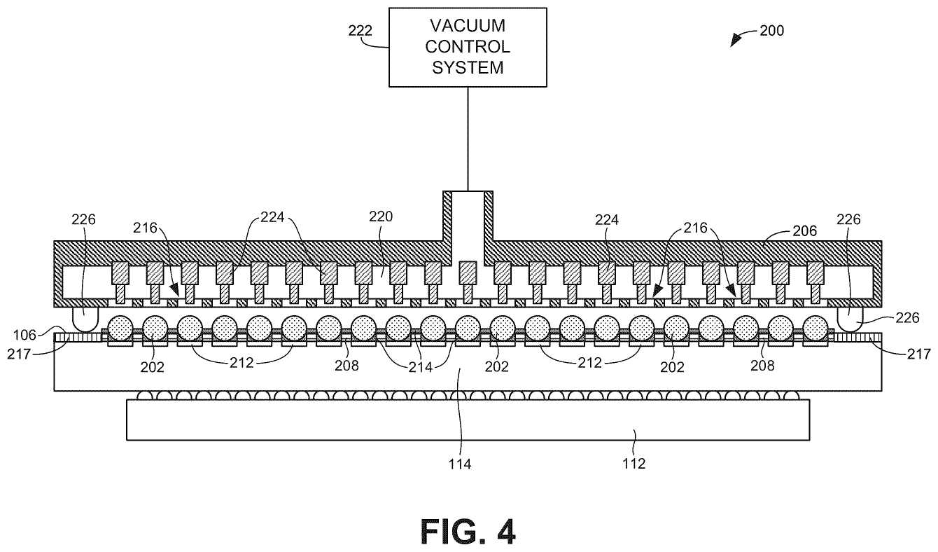

In some examples, the ball head 206 (also referred to as a ball arrangement plate) of the ball placement system 200 includes an array of holes 216 (most clearly shown in FIG. 4) in a bottom surface 218 of the ball head 206. In this example, the holes 216 open into an internal chamber 220 that is operatively coupled to a vacuum control system 222. In some examples, the vacuum control system 222 creates a vacuum within the internal chamber 220 to produce a suction force at each of the holes 216 that holds or retains a corresponding one of the balls 202. Thus, the ball head 206 is an example means for holding an array of solder balls. Although all of the holes 216 are shown as opening into a single internal chamber 220 that is operatively coupled to a single vacuum control system 222, in some examples, the inside of the ball head 206 may be divided into multiple chambers and/or in communication with more than one vacuum control system 222.

In this example, the holes 216 are dimensioned to be slightly smaller than the balls 202 so that the balls 202 do not get sucked into the internal chamber 220 but remain in place within the holes 216. The holes are arranged in an array corresponding to the intended arrangement of the balls 202 as the bumps 104 in their final position as the second level interconnects 122 of the IC package 100 of FIG. 1. That is, the arrangement of the holes 216 are designed to match the arrangement of the solder resist openings 210 on the package substrate 114. In some examples, once the ball head 206 (while holding the balls 202 in the holes 216) is positioned in alignment over the package assembly 204, the vacuum control system 222 turns off the vacuum within the internal chamber 220, thereby releasing the balls 202 to drop into place within respective ones of the solder resist openings 210. In some examples, ejection pins 224 are provided in the ball head 206 to extend and push out any balls 202 that may not have dropped due to the force of gravity. In the illustrated example, each ejection pin 224 is shown as an independently operated component. However, in other examples, some or all of the ejection pins 224 may be combined and operated using a common actuator. In some examples, the ejection pins 224 are omitted.

As shown in the illustrated example of FIG. 2, due to the warpage in the package assembly 204, the balls 202 held near the center of the ball head 206 (e.g., the balls to be placed near the center of the package substrate 114) are significantly farther away from the external surface 106 of the package substrate 114 than the balls 202 near the outer edge of the ball head (e.g., the balls to be placed near the outer edge of the package substrate 114). As the distance between the surface 106 of the package substrate 114 and the ball head 206 increases, the accuracy and/or precision in the placement of the balls 202 when dropped onto the substrate 114 decreases. As a result, the relatively large distance between the substrate 114 and the balls 202 near the middle of the ball head 206 will increase the likelihood that the balls will end up outside of or at least offset or out of alignment with their respective solder resist openings 210. In some instances, misalignment of the balls 202 with their respective solder resist openings 210 occurs because the increased height from which the balls fall result in the balls bouncing, rolling, or otherwise moving after hitting the package substrate 114.

To mitigate against the misplacement of balls 202 arising from large drop heights based on warpage in the package assembly 204, the example ball head 206 includes one or more example protrusions 226 that extend away from the bottom surface 218 of the ball head 206. The protrusions 226 are dimensioned to extend away from the bottom surface 218 of the ball head 206 farther than the balls 202 extend away from the bottom surface 218 when held in the holes 216. That is, the protrusions 226 extend beyond the balls 202 such that distal ends 228 of the protrusions 226 are closer to the package assembly 204 than anything else on the ball placement system 200. As a result, if the ball head 206 was moved towards the package assembly 204, the protrusions 226 would be the first component to contact the package assembly 204.

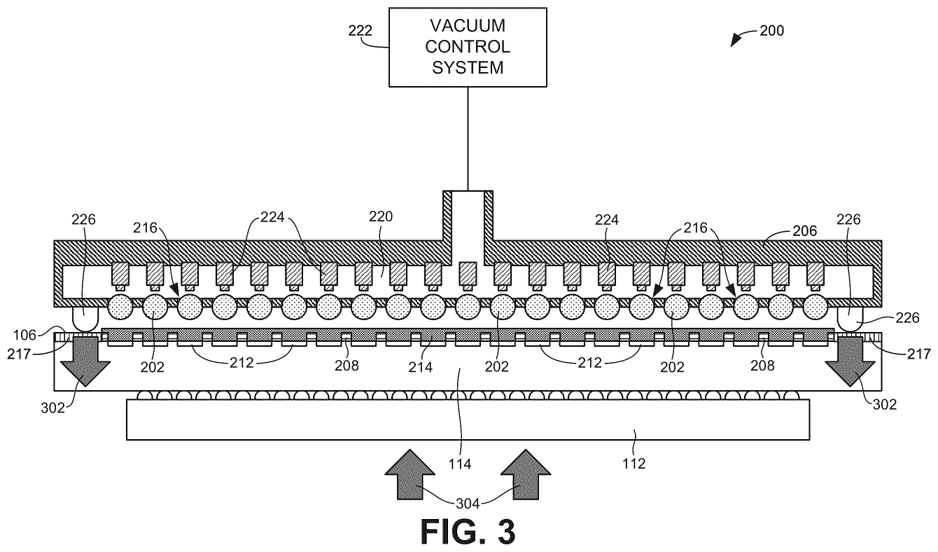

In some examples, the protrusions 226 are used to flatten the package assembly 204 by applying a force that counteracts the warpage in the assembly. Thus, the protrusions 226 are an example means for flattening the package substrate 114 and the die 112. Specifically, as illustrated in FIG. 3, the ball head 206 has been pressed down against the package assembly 204 by a downward force 302. An equal and opposite reactionary force 304 is applied to the die 112 by an underlying support table (not shown for the sake of clarity). The downward force 302 from the protrusions 226 above the package substrate 114 and the reactionary force 304 from the underlying support below the die 112 urge the package assembly into a more flattened state, as shown in FIG. 3, than the warped state represented in FIG. 2. As a result, as shown in FIG. 3, each of the balls 202 is held at approximately the same, relatively small distance from the package substrate 114 to enable consistent and reliable placement of the balls 202.

As shown in the illustrated example of FIG. 3, the only points of contact between the ball head 206 and the external surface 106 of the package substrate 114 is at the protrusions 226. That is, in some examples, the protrusions 226 are to contact the package substrate 114 without the balls 202 touching the package substrate. In this example, the relatively small distance that the balls 202 remain spaced apart from the external surface 106 of the package substrate 114 corresponds to the distance that the protrusions 226 extend beyond the balls 202 when held in the holes 216. In some examples, the distance that the protrusions 226 extend beyond the balls 202 is less than or equal to 100 microns so that the distance any of the balls 202 is to drop from the ball head 206 onto the package substrate will be less than or equal to approximately 100 microns. However, in other examples, different distances are possible (e.g., significantly less than 100 microns (e.g., less than 75 microns, less than 50 microns, etc.) or greater than 100 microns (e.g., between 100 microns and 200 microns)).

As shown in FIG. 3, the protrusions 226 are positioned on the ball head 206 so as to contact the external surface 106 of the package substrate 114 at the regions 217 that are spaced apart from the solder resist 208 and spaced apart from the flux material 214. In this way, there is little risk of the ball head 206 becoming contaminated by the flux material 214. That is, in some examples, the protrusions 226 are to contact the package substrate 114 without contacting flux material 214 on the package substrate 114.

FIG. 4 illustrates the ball head 206 urged against the package assembly 204 following the release or dropping of the balls 202 onto the package substrate 114. As represented in FIG. 4, the ejection pins 224 have been extended to push out each of the balls 202. Due to the relatively flat nature of the package substrate 114, none of the balls 202 have to fall very far and can, therefore, be precisely placed in each corresponding solder resist opening 210.

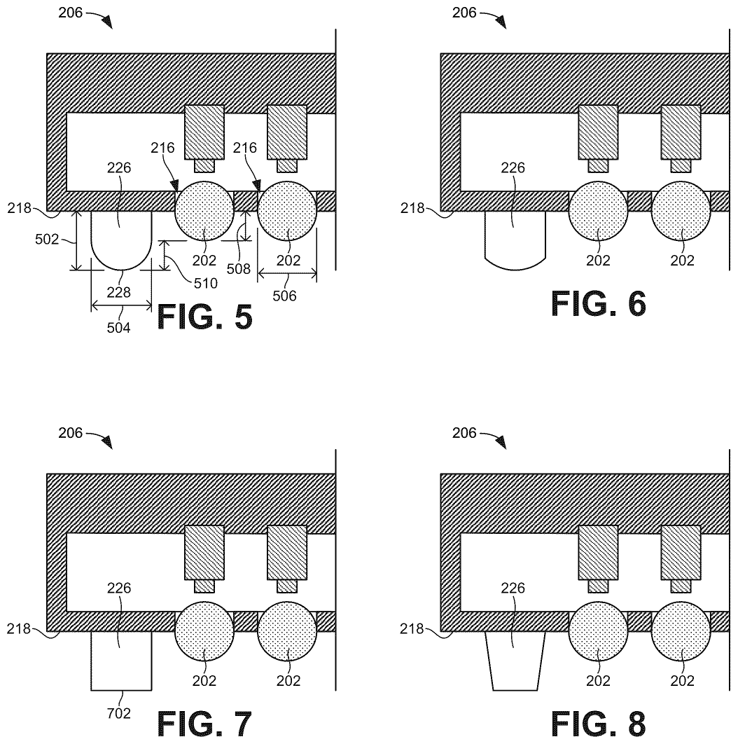

FIG. 5 is an enlarged view of a portion of the example ball head 206 demarcating dimensions associated with the balls 202 and the protrusions 226. As already described above, the example protrusions extend a first distance 502 away from the bottom surface 218 of the ball head 206. In this example, the first distance 502 is approximately equal to a width 504 of the protrusion 226. In other examples, the first distance 502 is greater than the width 504 (e.g., 1.5 times the width 504, twice the width 504, etc.). In other examples, the first distance 502 is less than the width 504 of the protrusions 226.

Each of the balls 202 has a diameter 506. As described above, the diameter 506 is slightly larger than the holes 216 to prevent the balls 202 from passing therethrough. As a result, when held in the holes 216, the balls 202 extend beyond the bottom surface 218 of the ball head by a second distance 508 that is equal to or greater than the radius (or one half the diameter 506) of the balls 202. As shown in the illustrated example, the protrusions 226 extend beyond the balls 202 by a third distance 510 that is equal to the difference between the first distance 502 and the second distance 508. In this example, the width 504 of the protrusions 226 is approximately equal to the diameter 506 of the balls 202. In other examples, the width 504 of the protrusions 226 may be greater than or less than the diameter 506 of the balls 202.

The particular dimensions of the protrusions 226 and the balls 202 can be any suitable dimensions. However, to provide a concrete example, the balls 202 may be 8 mil solder balls (with a diameter of approximately 200 microns). Thus, the second distance 508 that the balls 202 protrude beyond the bottom surface 218 of the ball head 206 (when the balls 202 are held in the holes 216) is approximately (or just under) 100 microns. To provide a reasonable gap between the balls 202 and the package substrate 114 onto which the balls 202 are to be placed (to avoid contamination of the ball head 206 by the flux material 214) while at the same time positioning the balls 202 relatively close to the package substrate to reduce (e.g., minimize) the drop height of the balls, the first distance 502 that the protrusion 226 extends away from the bottom surface 218 is approximately 200 microns. As a result, the third distance 510 is approximately (or just under) 100 microns. This third distance 510 defines the drop height for the balls 202 onto the package substrate 114.

FIGS. 6-8 are similar to FIG. 5 but show different cross-sectional shapes for the example protrusion 226. Specifically, FIG. 5 shows the protrusions have parallel lateral sides or walls and a rounded distal end 228. In the example of FIG. 5, the radius of curvature of the rounded end corresponds to one half the width 504 of the protrusions 226. FIG. 6 illustrates the protrusions 226 with a rounded distal end having a radius of curvature that is greater than the width 504 of the protrusions. The larger radius can help distribute the downward force 302 over a larger area of the package substrate 114 to reduce stress. Unlike FIGS. 5 and 6, the example protrusion 226 shown in FIG. 7 includes a planar surface 702 at the distal end to further increase the area of contact with the package substrate 114. In some examples, the planar surface 702 is substantially parallel (e.g., within +/−5° of exactly parallel) to the bottom surface 218 of the ball head 206. Unlike FIGS. 5-7, the example protrusions 226 shown in FIG. 8 includes angled or sloped lateral sides or walls. The example cross-sectional shapes for the protrusion 226 shown in the illustrated examples of FIGS. 6-8 are not mutually exclusive but may be combined in any suitable manner. Further, any other suitable shape for the protrusions may additionally or alternatively be implemented. for instance, in some examples, the lateral sides or walls may also be rounded or curved.

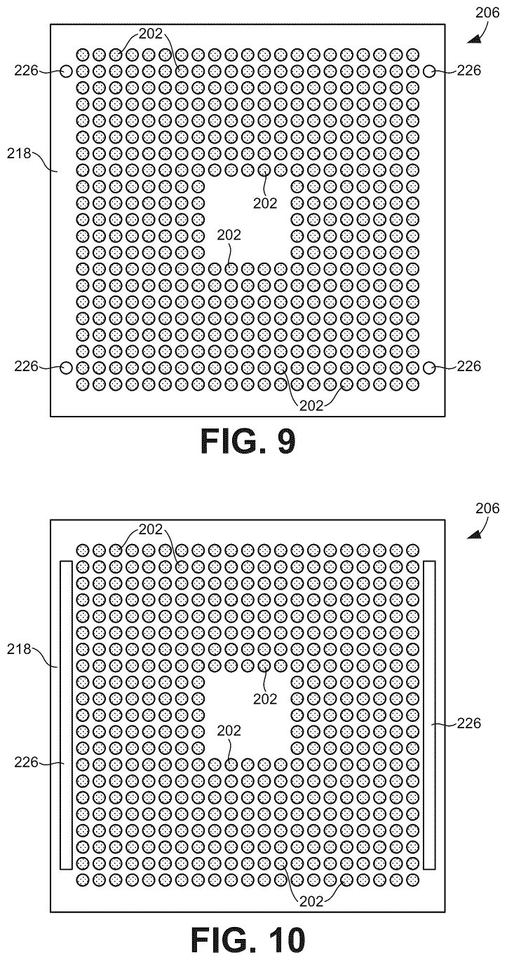

FIG. 9 is a bottom view of the example ball head 206 of FIG. 2. FIG. 9 illustrates the placement of the protrusions 226 relative to the array of balls 202. The particular arrangement of the array of balls 202 shown in FIG. 9 is for purposes of illustration and any other suitable arrangement and/or any other suitable number of balls may be implemented. In this example, the protrusions 226 are positioned adjacent and/or proximate to corners of the array of balls 202. In this manner, the protrusions 226 will contact the package substrate adjacent and/or proximate to different corners of the package substrate 114 when the ball head 206 is pressed against the substrate 114. In some examples, the protrusions 226 are located near the corners because the warpage in the package assembly 204 represented in FIG. 2 is such that the corners are at the highest point relative to the center of the package assembly 204 (corresponding to the lowest point). In some examples, if the warpage of the package assembly 204 is different, the protrusions 226 may be located at different locations. Further, in some examples, the particular location and/or layout of the protrusions 226 is determined based on the availability of space on the package substrate that can be contacted by the protrusions 226 that is spaced apart from the solder resist 208 and the flux material 214. For instance, in some examples, rather than the protrusions 226 being positioned outside of the array of balls 202 as shown, the protrusions 226 may be positioned in the middle and/or between adjacent balls 202 if the spacing of the balls and the associated design of the package substrate 114 permits the same.

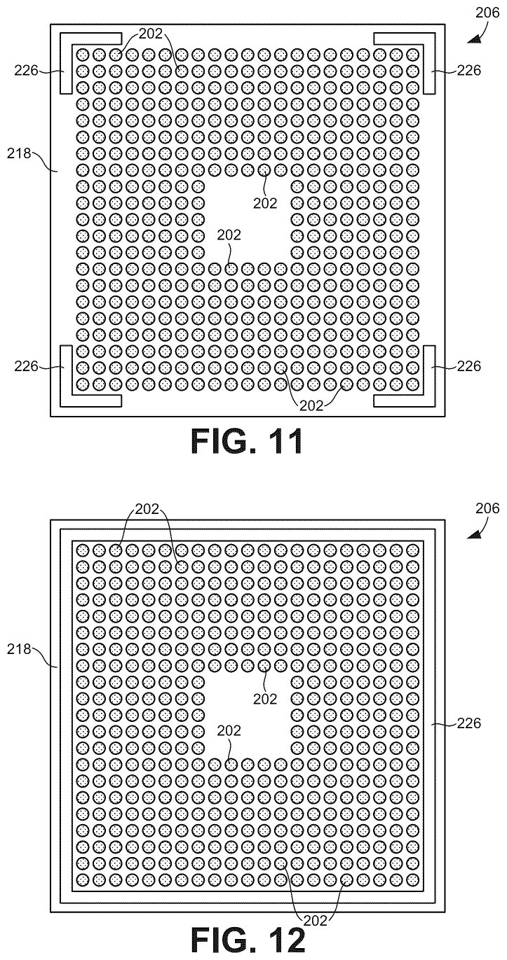

As shown in FIG. 9, the protrusions 226 have a pillar shape that protrudes away from the bottom surface 218 of the ball head 206. As used herein, a pillar shape means that the width or thickness of the protrusion 226 measured in a first direction along the surface 218 is approximately equal to or at least similar to (e.g., less than twice) the width or thickness of the protrusion 226 measured in a second direction along the surface 218 perpendicular to the first direction. In the illustrated example of FIG. 9, the pillar shape of the protrusions 226 is circular but any other suitable shape may alternatively be used (e.g., square, oval, rectangle, etc.). In some examples, the protrusions 226 are elongate in a direction extending along the bottom surface 218 of the ball head 206 (e.g., the protrusions 226 extend along a path that is substantially longer than (e.g., more than twice) a width (e.g., the width 504) of the protrusions 226 measured perpendicular to the path), as represented in the illustrated example of FIG. 10. In some examples, the width of the protrusion 226 may change along the elongate length of the protrusions. Further, in some examples, the elongate length of the protrusions 226 includes bends or corners as shown in FIG. 11. In some examples, the elongate length of a protrusion 226 defines a closed loop as shown in FIG. 12. Any other suitable design or shape for the location(s) and/or layout(s) of the protrusions may additionally or alternative be used. Further, the example location(s) and/or layout(s) for the protrusion 226 shown in the illustrated examples of FIGS. 9-12 are not mutually exclusive but may be combined in any suitable manner.

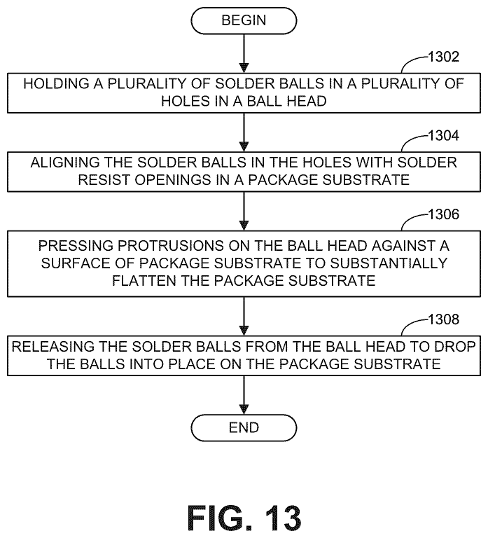

FIG. 13 is a flowchart representative of an example method of implementing the example ball placement system 200 of FIGS. 2-4 to manufacture the example IC package 100 of FIG. 1. In some examples, some or all of the operations outlined in the example method are performed automatically by fabrication equipment that is programmed to perform the operations. Although the example method is described with reference to the flowchart illustrated in FIG. 13, many other methods may alternatively be used. For example, the order or execution of the blocks may be changed, and/or some of the blocks described may be combined, divided, re-arranged, omitted, eliminated, and/or implemented in any other way. Furthermore, one or more additional operations may be implemented before, between, and/or after the blocks shown in the illustrated example.

The example method begins at block 1302 by the holding of a plurality of solder balls (e.g., the balls 202) in a plurality of holes (e.g., the holes 216) of the ball head (e.g., the ball head 206). As discussed above, in some examples, the balls 202 are picked up and held in the holes 216 based on a vacuum created in the internal chamber 220 of the ball head 206. At block 1304, the example method includes aligning the solder balls 202 in the holes 216 with solder resist openings (e.g., the solder resist openings 210) in a package substrate (e.g., the package substrate 114). At block 1306, the example method includes pressing protrusions (e.g., the protrusions 226) on the ball head 206 against a surface of the package substrate 114 to substantially flatten the package substrate 114. As used herein, “substantially flatten” means variation in height across the surface of the package substrate 114 is less than 50 microns. At block 1308, the example method includes releasing the solder balls 202 from the ball head 206 to drop the balls 202 into place on the package substrate 114. Thereafter, the example method of FIG. 13 ends.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

From the foregoing, it will be appreciated that example systems, methods, apparatus, and articles of manufacture have been disclosed that improve the placement of solder balls on package substrates for IC packages. Such improvements are made possible by flattening the package substrates (before the balls are dropped into place) using protrusions on the ball head that holds the balls in position before being dropped.

Further examples and combinations thereof include the following:

Example 1 includes an apparatus comprising a ball head including a first surface having an array of holes, the array of holes to hold a corresponding array of solder balls to be placed on a package substrate of an integrated circuit package, and a protrusion extending away from the first surface of the ball head, the protrusion positioned relative to the holes to contact a second surface of the package substrate when the solder balls are to be placed on the package substrate.

Example 2 includes the apparatus of example 1, wherein the protrusion is to extend away from the first surface by a first distance, and the solder balls, when held in the holes, are to extend away from the first surface by a second distance, the first distance greater than the second distance.

Example 3 includes the apparatus of example 2, wherein a difference between the first distance and the second distance is less than or equal to 100 microns.

Example 4 includes the apparatus of any one of examples 1-3, wherein the protrusion is positioned relative to the holes to contact the second surface of the package substrate at a point spaced apart from a solder resist on the package substrate and spaced apart from openings in the solder resist, the openings corresponding to where the solder balls are to be placed on the package substrate.

Example 5 includes the apparatus of any one of examples 1-4, wherein the protrusion is one of a plurality of protrusions extending away from the first surface.

Example 6 includes the apparatus of example 5, wherein different ones of the plurality of protrusions are positioned to contact the package substrate adjacent different corners of the package substrate.

Example 7 includes the apparatus of any one of examples 1-6, wherein the protrusion has a pillar shape.

Example 8 includes the apparatus of any one of examples 1-6, wherein the protrusion is elongate in a direction extending along the first surface.

Example 9 includes the apparatus of any one of examples 1-8, wherein the protrusion has a width that is approximately equal to a diameter of the solder balls.

Example 10 includes the apparatus of any one of examples 1-9, wherein the protrusion has a distal end that is rounded.

Example 11 includes the apparatus of example 10, wherein a radius of curvature of the rounded distal end is greater than half a width of the protrusion.

Example 12 includes the apparatus of any one of examples 1-12, wherein the protrusion has a third surface facing away from the first surface, the third surface corresponding to a portion of the protrusion farthest from the first surface, the third surface being planar and substantially parallel to the first surface.

Example 13 includes an apparatus comprising means for holding an array of solder balls to be placed in solder resist openings on a package substrate, and means for flattening the package substrate when the solder balls are to be placed on the solder resist openings, the means for flattening protruding from the means for holding.

Example 14 includes the apparatus of example 13, wherein the means for flattening is to contact the package substrate without the solder balls touching the package substrate.

Example 15 includes the apparatus of example 14, wherein the means for flattening is to contact the package substrate at a point spaced apart from flux material on the package substrate, the means for holding to release the solder balls to drop onto the flux material.

Example 16 includes the apparatus of any one of examples 13-15, wherein the means for flattening is distributed at different locations on the means for holding.

Example 17 includes the apparatus of example 16, wherein the different locations correspond to different corners of the array of solder balls.

Example 18 includes a method comprising holding a plurality of solder balls in a plurality of holes in a ball head, pressing a protrusion on the ball head against a surface of a package substrate, and releasing the solder balls from the ball head to place the solder balls on the package substrate.

Example 19 includes the method of example 18, wherein the pressing of the protrusion on the ball head against the surface of the package substrate is with a force to substantially flatten the package substrate.

Example 20 includes the method of any one of examples 18 or 19, further including aligning the solder balls in the holes in the ball head with solder resist openings in the package substrate before pressing the protrusion against the surface of the package substrate, the protrusion positioned relative to the holes so that, when the protrusion is pressed against the surface of the package substrate, the protrusion does not contact a solder resist associated with the solder resist openings.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. An apparatus comprising:
a ball head including a first surface having an array of holes, the array of holes to hold a corresponding array of solder balls to be placed on a package substrate of an integrated circuit package; and
a protrusion extending away from the first surface of the ball head, the protrusion positioned relative to the holes to contact a second surface of the package substrate when the solder balls are to be placed on the package substrate.

2. The apparatus of claim 1, wherein the protrusion is to extend away from the first surface by a first distance, and the solder balls, when held in the holes, are to extend away from the first surface by a second distance, the first distance greater than the second distance.

3. The apparatus of claim 2, wherein a difference between the first distance and the second distance is less than or equal to 100 microns.

4. The apparatus of claim 1, wherein the protrusion is positioned relative to the holes to contact the second surface of the package substrate at a point spaced apart from a solder resist on the package substrate and spaced apart from openings in the solder resist, the openings corresponding to where the solder balls are to be placed on the package substrate.

5. The apparatus of claim 1, wherein the protrusion is one of a plurality of protrusions extending away from the first surface.

6. The apparatus of claim 5, wherein different ones of the plurality of protrusions are positioned to contact the package substrate adjacent different corners of the package substrate.

7. The apparatus of claim 1, wherein the protrusion has a pillar shape.

8. The apparatus of claim 1, wherein the protrusion is elongate in a direction extending along the first surface.

9. The apparatus of claim 1, wherein the protrusion has a width that is approximately equal to a diameter of the solder balls.

10. The apparatus of claim 1, wherein the protrusion has a distal end that is rounded.

11. The apparatus of claim 10, wherein a radius of curvature of the rounded distal end is greater than half a width of the protrusion.

12. The apparatus of claim 1, wherein the protrusion has a third surface facing away from the first surface, the third surface corresponding to a portion of the protrusion farthest from the first surface, the third surface being planar and substantially parallel to the first surface.

13. An apparatus comprising:
means for holding an array of solder balls to be placed in solder resist openings on a package substrate; and
means for flattening the package substrate when the solder balls are to be placed on the solder resist openings, the means for flattening protruding from the means for holding.

14. The apparatus of claim 13, wherein the means for flattening is to contact the package substrate without the solder balls touching the package substrate.

15. The apparatus of claim 14, wherein the means for flattening is to contact the package substrate at a point spaced apart from flux material on the package substrate, the means for holding to release the solder balls to drop onto the flux material.

16. The apparatus of claim 13, wherein the means for flattening is distributed at different locations on the means for holding.

17. The apparatus of claim 16, wherein the different locations correspond to different corners of the array of solder balls.

18. A method comprising:
holding a plurality of solder balls in a plurality of holes in a ball head;
pressing a protrusion on the ball head against a surface of a package substrate; and
releasing the solder balls from the ball head to place the solder balls on the package substrate.

19. The method of claim 18, wherein the pressing of the protrusion on the ball head against the surface of the package substrate is with a force to substantially flatten the package substrate.

20. The method of claim 18, further including aligning the solder balls in the holes in the ball head with solder resist openings in the package substrate before pressing the protrusion against the surface of the package substrate, the protrusion positioned relative to the holes so that, when the protrusion is pressed against the surface of the package substrate, the protrusion does not contact a solder resist associated with the solder resist openings.
